(19) United States
(12) Patent Application Publication
(10) Pub. No.: US 2019/0271235 A1
(43) Pub. Date: Sep. 5, 2019

(54) Systems, Devices, and/or Methods for Managing Ceramic Coatings

(71) Applicant: Directed Vapor Technologies International, Inc., Charlottesville, VA (US)

(72) Inventor: Derek Hass, Charlottesville, VA (US)

(73) Assignee: Directed Vapor Technologies International, Inc., Charlottesville, VA (US)

(21) Appl. No.: 16/265,877

(22) Filed: Feb. 1, 2019

Related U.S. Application Data
(60) Provisional application No. 62/593,836, filed on Dec. 1, 2017.

(51) Int. Cl. F01D 5/28; C23C 14/02; C23C 4/02; C23C 28/04

(52) U.S. Cl. CPC F01D 5/288; C23C 14/02; F05D 2300/611; C23C 28/042; F05D 2300/17; C23C 4/02

(57) ABSTRACT

Certain exemplary embodiments can provide a method, which can comprise stabilizing adherence of a ceramic layer to a bond coat of a thermal barrier coating system, via incorporation of iron and cobalt into the bond coat at a given level. The bond coat can comprise MCrAlY, wherein M is selected from the group consisting of nickel, cobalt, iron and mixtures thereof.

### CROSS-REFERENCES TO RELATED APPLICATIONS

This application claims priority to, and incorporates by reference herein in its entirety, pending U.S. Provisional Patent Application Ser. No. 62/593,836 (Attorney Docket No. 1099-11), filed Dec. 2, 2017.

### GOVERNMENT SUPPORT

This disclosure, at least in part, was developed with support from Dept. of Energy through grant DE-SC0013098, entitled Advanced Bond Coats for Thermal Barrier Coating Systems Based on High Entropy Alloys. The Government may have certain rights to the invention, as described in the grant terms and conditions SBIR/STTR-GTC-0024, Patent Rights, and SBIR/STTR-GTC-0025, Rights in Data—SBIR/STTR Program.

### BRIEF DESCRIPTION OF THE DRAWINGS

Each of FIGS. 1-22 is executed in color.

A wide variety of potential practical and useful embodiments will be more readily understood through the following detailed description of certain exemplary embodiments, with reference to the accompanying exemplary drawings in which:

FIG. 1 is a schematic diagram of an exemplary embodiment of a crucible set-up for the creation of arrays of compositionally unique bond coats based on HEAs;

FIG. 2 is a schematic diagram of a coater set-up for the creation of arrays of compositionally unique bond coats based on HEAs;

FIG. 3 is a schematic diagram of a substrate array to be used to combinatorial experiments;

FIG. 4A is a photograph of an experimental set-up for the quasi-combinatorial experiments conducted during the Phase I effort;

FIG. 4B is a photograph of an experimental set-up for the quasi-combinatorial experiments conducted during the Phase I effort;

FIG. 5 is a photograph of a coated substrate array. The coupons are numbered from 1 to 12 going from left to right;

FIG. 6 is a photograph of a production scale DVD system with installed enhanced plasma activation system and co-evaporation of two or more source rods and heating using gravel (metal or zirconia) for radiant heating of a substrate;

FIG. 7 is a set of photographs of an experimental set-up utilized to applied 7YSZ coatings onto the HEA bond coated coupons created during the Phase I effort;

FIG. 8 is a plot showing the EDS measured compositional gradients for the HEA-1 quasi-combinatorial experiment;

FIG. 9 is a plot showing the EDS measured compositional gradients for the HEA-4 quasi-combinatorial experiment;

FIG. 10 is a set of photographs of surface microstructure of the as-deposited bond coats from HEA-1;

FIG. 11 is a set of photographs of surface microstructure of the as-deposited bond coats from HEA-4;

FIG. 12 is a set of photographs of NiAlCr coatings applied onto A) a grit blast substrate and B) a polished substrate. Note the improved density of the coating/substrate interface for the polished substrate;

FIG. 13 is a plot showing relative thermal spallation resistance of TBC systems containing HEA bond coats from the HEA-1 quasi-combinatorial experiment. Green indicates compositions that fit the description of HEA alloys and also have promising cyclic oxidation lifetimes. Red indicates the composition does not fit the description of an HEA alloy;

FIG. 14 is a plot showing relative spallation resistance of TBC systems containing HEA bond coats from the HEA-3 quasi-combinatorial experiment. Green indicates compositions that fit the description of HEA alloys and also have promising cyclic oxidation lifetimes. Red indicates the composition does not fit the description of an HEA alloy;

FIG. 15 is a plot showing relative spallation resistance of TBC systems containing HEA bond coats from the HEA-4 quasi-combinatorial experiment. Green indicates compositions that fit the description of HEA alloys and also have promising cyclic oxidation lifetimes. Red indicates the composition does not fit the description of an HEA alloy;

FIG. 16 is a set of photographs of TBC systems containing HEA bond coats during thermal spallation testing;

FIG. 17 is a plot and a photograph showing results from a range of NiFeCoAlCr alloy compositions that were deposited and used as bond coats for TBC systems (having a 7YSZ top coat). The results indicated that the TBC system lifetimes were a function of the Ni:Fe:Co ratio with samples 4 and 8 giving the best performance;

FIG. 18 is a set of photographs, a set of tables, and a set of plots showing results from composition of samples 4 and 8 is given both in the as-deposited condition and following thermal exposure;

FIG. 19 is a plot and a photograph showing results from a range of NiCoMnAlCr alloy compositions were deposited and used as bond coats for TBC systems (having a 7YSZ top coat). The results indicated that the TBC system lifetimes were a function of the Ni:Mn:Co ratio with samples 7 and 12 giving the best performance; and

FIG. 20 is a set of photographs, a set of tables, and a set of plots showing results from composition of NiCoMnAlCr alloy compositions that were deposited and used as bond coats for TBC systems (having a 7YSZ top coat). The results indicated that the TBC system lifetimes were a function of the Ni:Mn:Co ratio with samples 7 and 12 giving the best performance.

### DETAILED DESCRIPTION

Certain exemplary embodiments can provide a method, which can comprise stabilizing adherence of a ceramic layer to a bond coat of a thermal barrier coating system, via incorporation of iron and cobalt into the bond coat at a given level. The bond coat can comprise MCrAlY, wherein M is selected from the group consisting of nickel, cobalt, iron and mixtures thereof.

The availability of ultraclean, abundant, low-cost domestic energy in the United States is important to providing economic prosperity, strengthening energy independence, and enhancing environmental quality. This is driving the development of innovative, cost effective technologies for improving the efficiency and environmental performance of advanced large scale industrial and utility fossil energy power generation and natural gas recovery systems. To aid this, the development of advanced thermal barrier coating (“TBC”) systems used to enhance the temperature capability of gas turbine engine blades and vanes are of interest.

A TBC system works by creating a thermally insulating layer between the hot engine gases and the air-cooled, nickel based superalloy component. The resulting temperature drop across the coating “protects” the component surface by lowering the temperature that it is exposed to. Certain exemplary TBC systems comprise a bond coat, a thermally grown oxide (“TGO”), and a thermally insulating ceramic top coat. The bond coat can provide protection to a superalloy substrate from oxidation and hot corrosion attack and to form an adherent TGO on its surface. With the increasing service temperature demand and desire for fuel flexibility in advanced gas turbines engines, certain exemplary embodiments provide novel bond coat compositions that are also relatively ductile, strong, and stable at higher temperature and in extreme environments, and also limit the substrate/coating interaction even substantially without diffusion barriers.

One approach for the development of advanced TBC bond coats having enhanced high temperature capability is through the use of high-entropy alloys (“HEAs”). These alloys are combinations of five or more elements having unique combinations of strength, ductility and thermal stability due to their simple underlying lattices (BCC, FCC) and their very high entropy of mixing compared to unwanted intermetallic compounds. Alloys based on these concepts when combined with minor alloying additions may also demonstrate excellent oxidation and hot corrosion resistance making them of high interest as bond coats for TBCs or even as next generation structural alloys for gas turbine components that may not require the application of oxidation resistant coatings.

Certain exemplary embodiments provide for the formation of novel HEA-based alloys designed to have enhanced high temperature mechanical properties and oxidation performance over currently employed TBC bond coats. The use of multi-source evaporation techniques have been employed to provide unique control of the deposited alloy composition and enable thick film, quasi-combinatorial synthesis techniques to aid the determination of compositions of interest as TBC bond coats or high temperature structural materials. The results demonstrated the ability to obtain suitable lateral compositional gradients across a substrate array using the assembled quasi-combinatorial experimental set-up to enable the creation of a range of compositionally unique HEA bond coats. The HEA bond coats were then incorporated into TBC coating systems (substrate/HEA bond coat/Zirconia—approximately 7 weight % Yttria (“7YSZ”) top coat). Based the thermal spallation testing of the resulting TBC systems, two candidate alloys have been identified that meet the compositional criteria for an HEA composition, form protective alumina oxide scales and have good cyclic oxidation performance in TBC systems. Optimization of the composition these alloys can be via rare earth additions and/or microstructure (e.g., via modification of plasma activation conditions).

### 1.0 Introduction:

### 1.1 High Entropy Alloys:

High entropy alloys (“HEAs”) are alloys with five or more principal elements (each having a concentration between approximately 5 and approximately 35 atomic %). HEAs can have significantly higher mixing entropies than conventional alloys which results in the formation of solid solution phases with simple crystal structures. The high mixing entropy lowers the Gibbs free energy, G, for formation for the solid solution phases (as expressed via an equation G=H−TS; where H is enthalpy, T is Temperature and S is entropy) making them more likely to form than the intermetallic compounds, which typically can result in relatively poor engineering properties. Interestingly, HEAs can have in enhanced alloy properties in many areas including excellent high temperature strength, good structural stability, low diffusion coefficients, good creep resistance and good oxidation and corrosion resistance. The high temperature strength and stability is the result of large solid solution strengthening effects due to the lattice distortions that result from the incorporation of larger and smaller atoms than typically found in a given lattice. This distortion can impede dislocation motion to increase alloy strength. The diffusion and phase transformation kinetics of these alloys can be unusually low for similar reasons. In addition, the extreme amount of alloying elements leads to different bonding arrangements and therefore different local energies at different points on the lattice. This can result in the existence of “high-energy sites” which reduce a probability of atom movement. These effects make well designed HEAs excellent candidates for next generation, high temperature structural alloys or as high temperature coatings. In certain exemplary embodiments, HEAs are used as advanced bond coats for thermal barrier coating systems used on gas turbine engine components.

### 1.2 Thermal Barrier Coatings for Use in Advanced Gas Turbines Engines:

Of the alternate strategies for achieving higher turbine engine gas inlet temperatures, one of the highest potential near-term gain is from fully exploiting the insulating abilities of thermal barrier coating (“TBC”) systems. Thus, the development of highly durable TBC systems that can withstand high thermal loads can be of value to advanced gas turbines for power system designs. A TBC system works by creating a thermally insulating layer between the hot engine gases and the air-cooled component. The resulting temperature drop across the coating (approximately 170° C. or greater is possible) “protects” the component surface by lowering the temperature that it is exposed to. Certain exemplary TBC systems comprise a bond coat, a thermally grown oxide (“TGO”), and a thermally insulating ceramic (top coat). In power applications, the bond coat can either be a MCrAlY (where M=Ni or NiCo) based coating or a platinum aluminide. The bond coat can provide protection to the superalloy substrate from oxidation and hot corrosion attack and to form an adherent TGO on its surface. The thermal barrier layer (top coat) can be approximately 7 weight % yttria stabilized zirconia (7YSZ) with a thickness of approximately 100-1000 um. The complex gaseous environments which are created during the conversion of fossil fuels in gas turbines can result in significant challenges for a TBC system such as oxidizing, sulfidizing and water vapor containing conditions. The multi-oxidant process environments are often non-equilibrium and can vary in degree of aggressiveness. Thus, TBC's used in these situations should be resistant to a range of oxidizing-sulfidizing environment. Additionally, due to the requirement of fuel flexibility for advanced gas turbines for power application, the TBC systems should be capable of surviving higher than normal temperature exposures, elevated moisture contents and the unpredictable TBC loss from the impingement of engine contaminants.

The performance of TBC systems can be related to the nature of the TGO scale that forms during service. As a result, bond coat compositions can be designed from materials that promote excellent high temperature oxidation resistance. Alumina forming alloys with a nickel or cobalt base can be used to accomplish this. In systems of this type, the life-limiting feature of TBCs can be delamination of the ceramic topcoat originating near the TBC/TGO or TGO/bond coat interface. Such failures can result from misfit stresses, which result from thermal expansion difference between the TGO and the bond coat, and TGO growth stresses, which increase with the thickness of the TGO. As TGO thickness can exceed several microns, these stresses can drive lateral crack propagation, which result in the failure of the TBC (spallation of the top coat). In addition, if the TGO forms a non-planar interface with the ceramic topcoat (i.e. rumpling), stresses within it intensify, leading to cracking at even thinner TGO thicknesses. Coating systems with high strength/creep resistant bond coats that result in slow growing, planar TGO layers that resist aluminum depletion are believed to be of value to the development of more durable TBC systems. Bond coats with tailored coefficients of thermal expansion (“CTEs”) that limit CTE related stresses in the TGO might also aid this goal.

### 2.0 Results

### 2.1 Define HEA Compositions

When considering the development of novel bond coats based on HEAs, comprising at least five major alloying components between approximately 5 and 35 atomic %, care can be taken to simplify the compositional degrees of freedom based on the engineering criteria of the end solution. For example, for oxidation resistance, alloying elements that promote the formation of a protection oxide scale can be utilized when considering HEAs that could provide improvements in bond coat systems. Certain exemplary embodiments can comprise Al and due to its beneficial effect on the formation of the desired alpha-alumina TGOs, Cr. Levels of Al and Cr can be set to get good oxidation performance in Ni-based alloys. Thus, if a Ni based composition, is used a good estimate of the desired Al and Cr levels can be made. By choosing a starting Ni—Cr—Al composition, compositional selection can be simplified to determining the Ni—Al—Cr composition and then choosing alloying elements (at least two) that can substitute for Ni atoms and enable the formation of a HEA alloy.

Using Ni—Al—Cr (atomic %) as a base, the selection of alloy elements, which can be substituted for Ni, is then performed. One approach for selecting these elements is to identify elements that were not likely to greatly affect the existing phase constitution space when substituted in for Ni based on Hume-Rothery predictions. Such alloys may have a chance at retaining the capability for precipitate strengthening through the formation of a fine distribution of a BCC phase in an FCC matrix along with the increase in solid solution strengthening enabled by the formation of the HEA. An initial list of potential elements to be considered as alloy additions along with properties of interest is given in Table 1. In general, elements with small differences in atom size or electronegativity have a strong likelihood of forming single phase alloys. HEAs that have been successful created also provide some guidance. For example Ni—Al—Cr—Cu—Co—Fe is a HEA. Mn has also been incorporated into similar HEAs. Other elements have been added to systems of this type such as Ti, Mo, Si, Zr, Nd, Nb, V, Y, Sn, Zn, C although in some cases these can lead to intermetallic phase formation. Nevertheless, such examples can still be used to guide alloy selection. Based on the above arguments, the work in this task was used to finalize the selection of four elements to be used in the quasi-combinatorial experiments described in Task 2 below.

TABLE 1
Elements of Interest for HEA Creation [6]

| | | Atom Size | Electro- | Vapor Pressure |
|---|---|---|---|---|
| Element | Tₘ (K) | (pm) | negativity | mm-HG (@2000K) |
| Ni | 1,728 | 126 | 1.91 | 2 × 10⁻¹ |
| Al | 933 | 141 | 1.61 | 6 |
| Cr | 2,180 | 130 | 1.66 | 1 |
| Cu | 1,358 | 126 | 1.9 | 3 |
| Co | 1,768 | 124 | 1.88 | 2 × 10⁻¹ |
| Fe | 1,811 | 126 | 1.83 | 3 × 10⁻¹ |
| Ti | 1,941 | 142 | 1.54 | 1 × 10⁻² |
| Mn | 1,519 | 132 | 1.55 | 1 × 10² |
| Mo | 2896 | 139 | 2.16 | 2 × 10⁻⁷ |
| Nd | 1,289 | 182 | 1.14 | — |
| Nb | 2,750 | 150 | 1.6 | 3 × 10⁻⁹ |
| V | 2,183 | 134 | 1.63 | 2 × 10⁻³ |
| Y | 1,795 | 173 | 1.22 | 2 × 10⁻² |
| Si | 1,687 | 112 | 1.9 | 3 × 10⁻² |

The elements Cu, Co, Fe and Mn were chosen as additions to the NiAlCr core components. An initial test matrix was assembled as given in Table 2.

TABLE 2
Planned Quasi-Combinatorial Experiments for Phase I

| | Co | Fe | Cu | Mn |
|---|---|---|---|---|
| Co | [symbol] | [symbol] | [symbol] | [symbol] |
| Fe | Fe—Co | [symbol] | [symbol] | [symbol] |
| Cu | Cu—Co | Cu—Fe | [symbol] | [symbol] |
| Mn | Mn—Co | Mn—Fe | Mn—Cu | [symbol] |

Based on this down-selection, four source rod compositions were ordered for use in Task 2 below. These included:

HEA-A: approximately Ni—67.58%; Al—20.76%; Cr—9.79%; Si—1.81%; Y—0.06% (in atomic %).

HEA-B: approximately Fe—67.58%; Al—20.76%; Cr—9.79%; Si—1.81%; Y—0.06% (in atomic %).

HEA-C: approximately Mn—67.58%; Al—20.76%; Cr—9.79%; Si—1.81%; Y—0.06% (in atomic %).

HEA-D: approximately Cu—67.58%; Al—20.76%; Cr—9.79%; Si—1.81%; Y—0.06% (in atomic %).

HEA-E: approximately Co—67.58%; Al—20.76%; Cr—9.79%; Si—1.81%; Y—0.06% (in atomic %).

The Mn-rich source (HEA-C) could not be effectively manufactured due to the brittleness of the alloy and thus, it was removed from the test matrix. As a result, the final test matrix is given in Table 3.

TABLE 3
Planned Quasi-Combinatorial Experiments for Phase I

| | Co | Fe | Cu |
|---|---|---|---|
| Co | [symbol] | [symbol] | [symbol] |
| Fe | Fe—Co | [symbol] | [symbol] |
| Cu | Cu—Co | Cu—Fe | [symbol] |

### 2.2 HEA Bond Coat Deposition

Work in this subtask was performed to determine the directed vapor deposition (“DVD”) processing conditions to deposit the coating compositional ranges identified during Task 1 onto test coupons. To achieve the desired density of the as-deposited coatings, plasma activation was used. Plasma activation was used to ionize the vapor atoms and a substrate bias was used to attract the ionized atoms to the substrate (thus increasing their energy during impact). This approach increased the kinetic energy of depositing atoms to yield high adatom surface mobility. Plasma-activation in DVD was performed by a hollow-cathode plasma unit capable of producing a high-density plasma in the system's gas and vapor stream. The particular hollow cathode arc plasma technology used in DVD was able to ionize a large percentage of all gas and vapor species in the mixed stream flowing towards the coating surface.

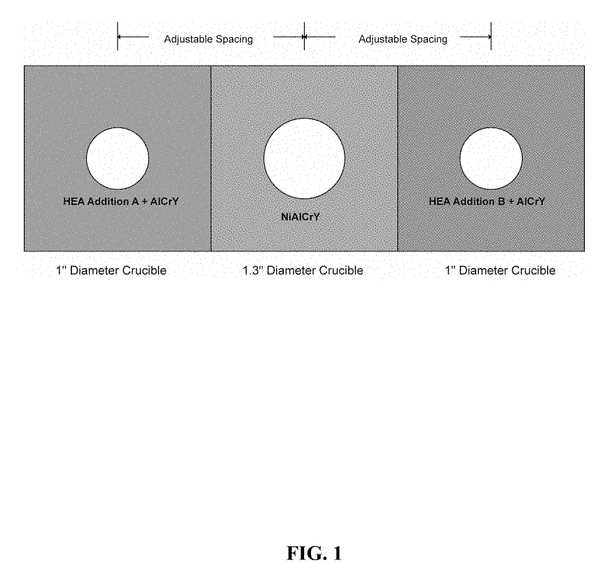

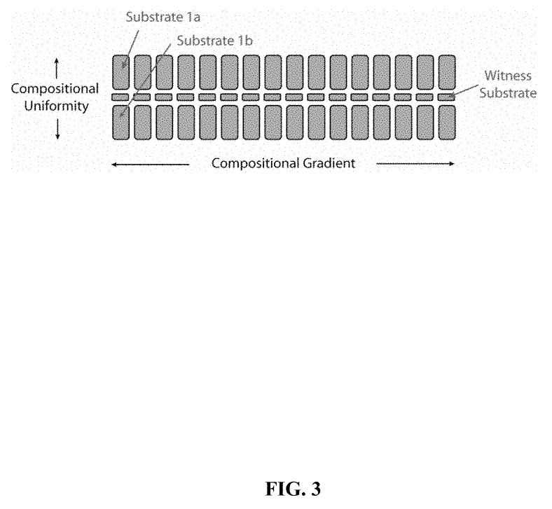

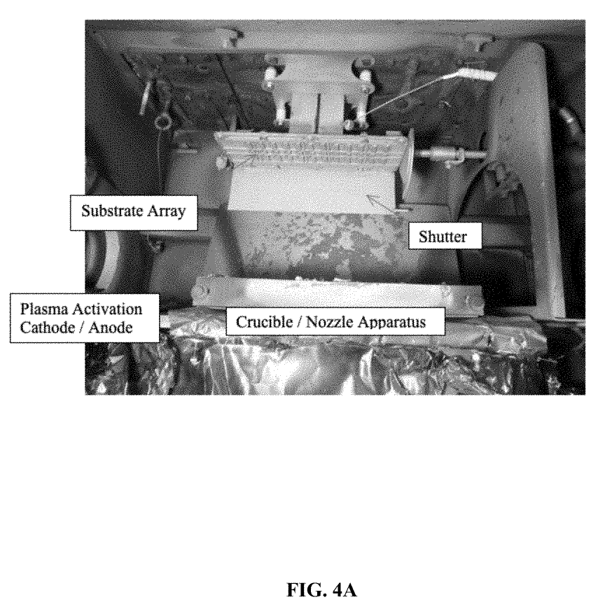

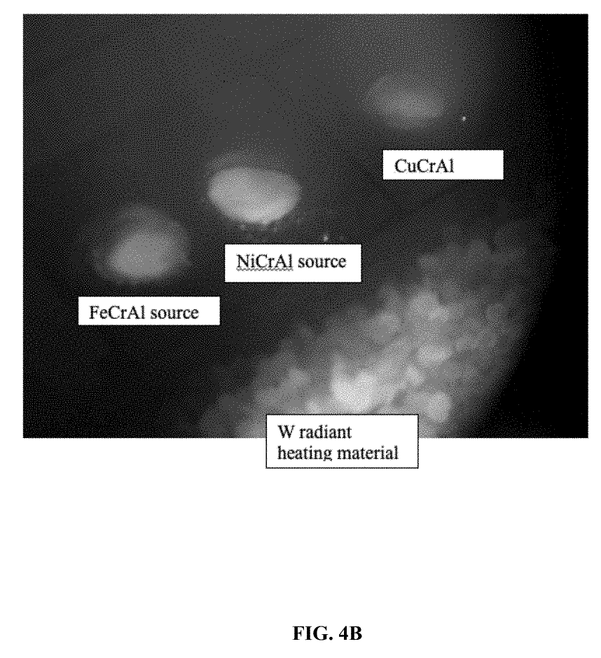

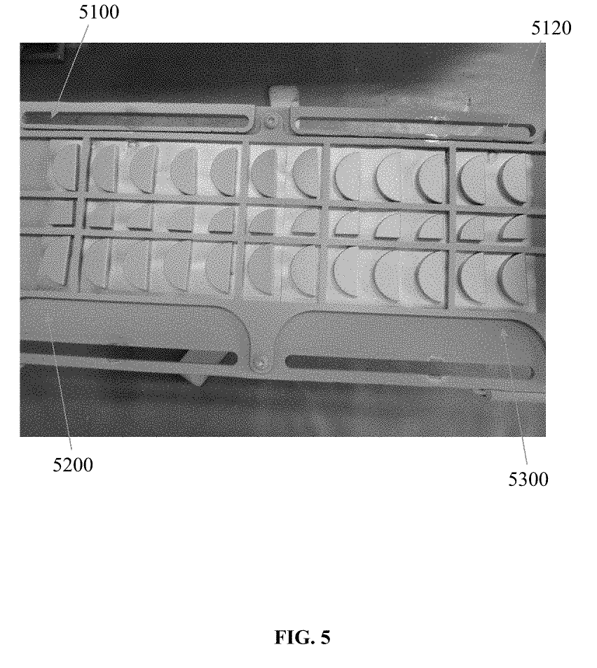

Multi-source evaporation approaches were used to obtain the desired coating compositions. In this stage of the work, the multiple source co-evaporation approach was set-up to enable the creation of lateral compositional gradients as shown in FIGS. 4 and 5. Co-evaporation from crucibles containing alloy source rods having a given spacing was used to create lateral compositional gradients (in the x-directions) as shown in FIG. 1. By adding determined levels of Al, Cr and Y to each source the composition of these elements can be held constant across the substrate array while having of range of Ni, HEA addition A and HEA addition B levels such that a range of potential compositions could be assessed in a given experiment. This set-up was effective for HEA additions having similar vapor pressures as Al, Cr and Y; however, the use of an additional crucible could be used in Phase II to assess elements that do not conform to this criterion. The key DVD process variables utilized to obtain dense, defect-free coatings have been determined and can be used to assure relatively microstructurally uniform coatings. Radiant heating was used to increase the substrate temperature to 800-1000° C. during the deposition run. The combinatorial bond coats were then deposited onto an array of CMSX-4 substrates (approximately 0.5″×1″). Each compositionally unique position comprised two CMSX-4 substrates and a small witness sample for compositional assessment, FIG. 3. For the Phase 1 testing, the evaporated fluxes of each source were planned to be equal. Additional compositional space could also be assessed using this set-up by altering the relative evaporation rates of each source; the source-to-source spacing and the operating chamber pressure. Such modifications were used in Phase II during compositional optimization.

FIG. 1—Crucible set-up for the creation of arrays of compositionally unique bond coats based on HEAs.

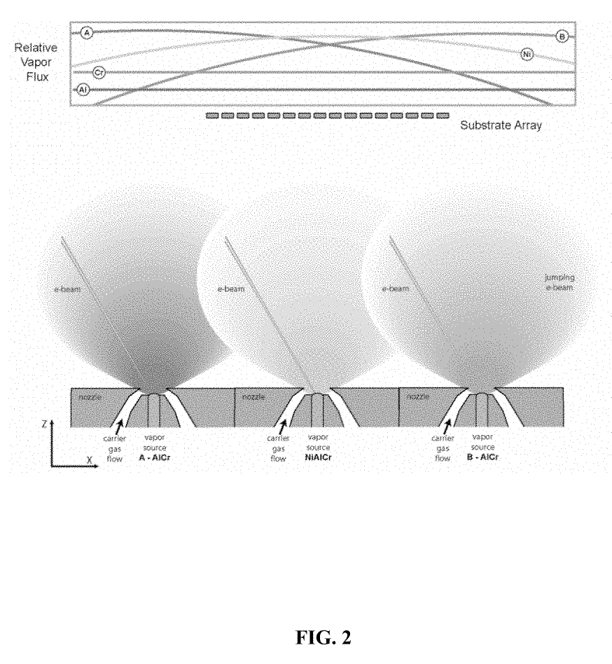

FIG. 2—Coater set-up for the creation of arrays of compositionally unique bond coats based on HEAs.

FIG. 3—Substrate array to be used to combinatorial experiments.

The resulting experimental set-up for the Phase I effort is shown in FIG. 4. The substrate array was located above the crucible/nozzle apparatus used to create the compositionally graded vapor flux. The plasma activation system was utilized to ionize a percentage of the vapor and carrier gas atoms to enable higher energy deposition. The melt pools from the three evaporation sources are shown in FIG. 4 along with the radiation heating source. The substrate array following HEA bond coat application is shown in FIG. 5. Table 4 gives the processing conditions for the bond coat application experiments.

FIG. 4—Experimental set-up for the quasi-combinatorial experiments conducted during the Phase I effort.

FIG. 5—Coated substrate array. The coupons are numbered from 1 to 12 going from left to right.

TABLE 4
Experimental Conditions for the HEA Bond Coat Applications

| | | HEA-B | HEA-D | HEA-E | | | | |
|---|---|---|---|---|---|---|---|---|
| | HEA-A | Change | Change | Change | | | | |
| Run | Change in | in mass | in mass | in mass | Time | Target | Carrier | Plasma |
| Code | mass (g) | (g) | (g) | (g) | (min) | Pressure | Gas | Current |
| HEA-4 | 13.93 | 7.34 | — | 7.54 | 45 | 8 Pa | Ar | 100 |
| HEA-3 | 10.8 | — | 3.69 | 11.68 | 45 | 8 Pa | Ar | 100 |
| HEA-1 | 18.7 | 24.84 | 11.12 | — | 55.7 | 8 Pa | Ar | 100 |

### 2.3 TBC Top Coat Deposition:

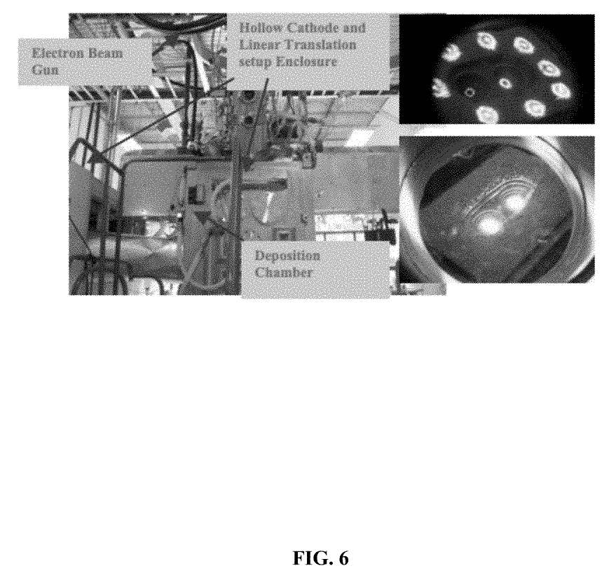

The production scale DVD coater was also well equipped for top coat deposition, FIG. 6. This process was demonstrated in prior work to enable the creation of highly durable TBC top coats. This coater allows for the co-evaporation of at least two 1.3″ diameter source rods to enable the high rate deposition of TBC ceramic materials, complex oxide chemistries having large vapor pressure differences between the different oxide components and multi-layered TBCs on large area components. This set-up allows for deposition of substantially compositionally uniform 7YSZ top coats onto the substrate arrays onto which the compositional graded bond coats can be applied. The resulting TBC systems underwent thermal spallation testing in Task 3 below.

FIG. 6—Digital image of the DVTI's production scale DVD system with installed enhanced plasma activation system and co-evaporation of two or more source rods and heating using gravel (metal or zirconia) for radiant heating of a substrate.

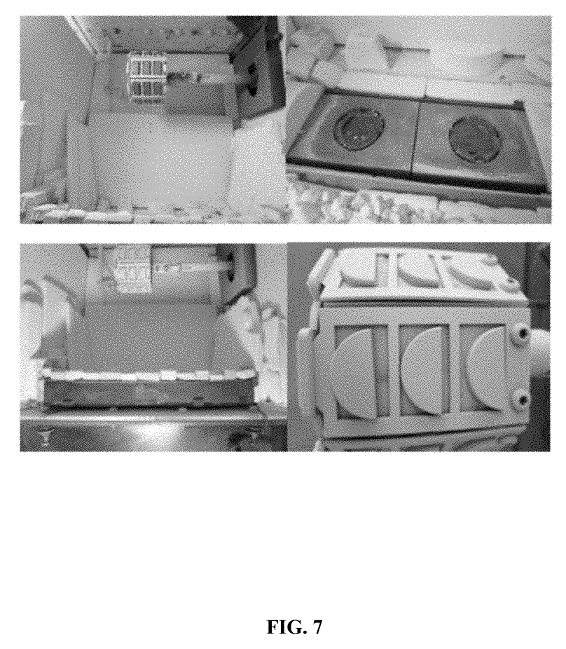

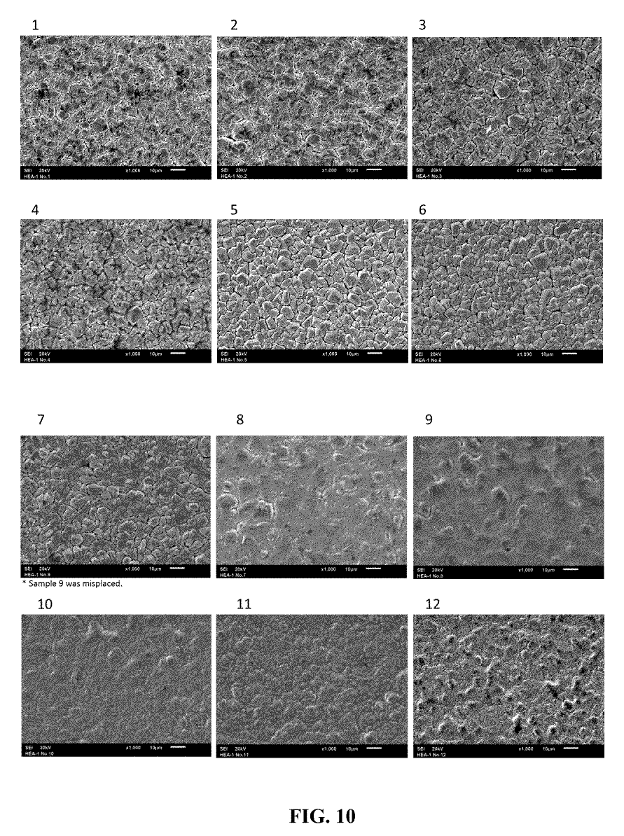

Following application of the HEA bond coats, a uniform, 7YSZ top coat was applied to the bond coated substrates. The experimental set-up for the 7YSZ application is shown in FIG. 10. Two approximately 1.3″ diameter 7YSZ sources were utilized for this purpose, FIG. 7. An octagonal, 24 coupon substrate holder was designed and constructed for this purpose. The resulting 7YSZ coating TBC systems are shown in FIG. 7.

FIG. 7—Experimental set-up utilized to applied 7YSZ coatings onto the HEA bond coated coupons created during the Phase I effort.

### 2.4: Characterization and Performance Analysis of TBC System

In this task, coating analysis was performed to assess the performance of the TBC systems created during Task 2. The key advantage to the experimental approach chosen for this work is that compositionally unique bond coats based on HEAs are placed into complete TBC systems at actual scale. This enabled the performance of the modified systems to be measured directly using cyclic oxidation testing. Such tests were not perfect and multiple samples of the same type were utilized to provide highly accurate lifetime data, however, even with this in mind the use of such approaches as a parallel screening test was anticipated to yield far superior data (in terms of accuracy) as compared with existing miniaturized mechanical testing techniques that could measure properties that would need to be extrapolated to TBC lifetime data. As a result, the characterization and performance analysis comprised a screening cyclic oxidation test followed by scanning electron microscope/energy-dispersive X-ray spectroscopy (“SEM/EDS”) characterization of a witness sample for good performing samples. Selected isothermal oxidation tests were also conducted on the HEA bond coats. The output of the SEM/EDS characterization was used to guide further experiments.

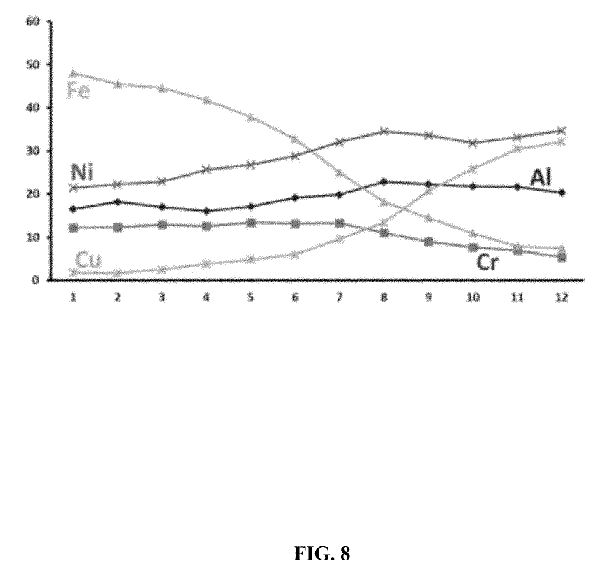

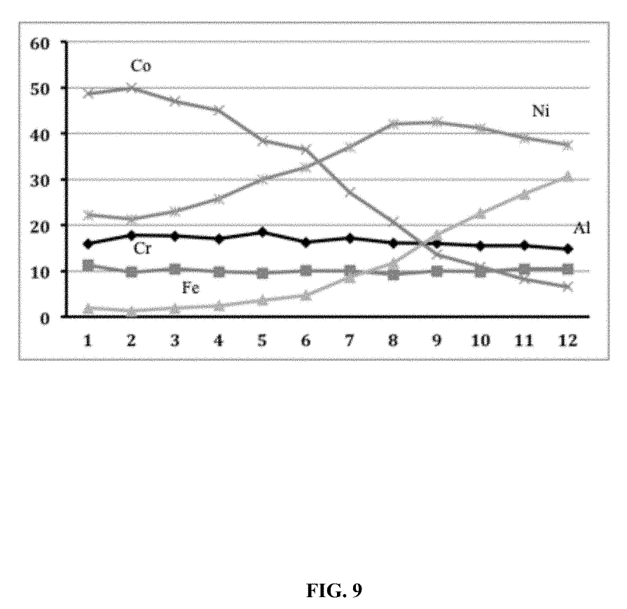

During this task, SEM/EDS and wavelength dispersive spectroscopy (“WDS”) were utilized to assess the composition and microstructure of the resulting HEA bond coats. EDS measurements of the surface composition of the substrate arrays are given in Tables 5 and 6 and FIGS. 8 and 9. Note that the resulting compositional gradients are quite similar to those desired in FIG. 2 above with the Ni, Cu, Co and Fe sources having a substantial compositional gradient and the Al and Cr sources having very little compositional changes from left to right (this is especially the case for HEA-4). It should also be noted that some of the resulting coatings do not fit the description of an HEA alloy as one of the components is either too low (i.e. below approximately 5 atomic %) or too high (i.e. above approximately 35 atomic %). These positions are noted in red on Tables 5 and 6.

FIG. 8—Plot showing the EDS measured compositional gradients for the HEA-1 quasi-combinatorial experiment.

TABLE 5
EDS Measured Coating Compositions from the HEA-1 quasi-
combinatorial experiment

| | Al | Cr | Fe | Ni | Cu |
|---|---|---|---|---|---|
| Sample 1 | 17 ± 1.1 | 12 ± 1.0 | 48 ± 1.7 | 21 ± 0.8 | 2 ± 1.1 |
| Sample 2 | 18 ± 1.4 | 12 ± 0.6 | 45 ± 0.6 | 22 ± 1.2 | 2 ± 0.6 |
| Sample 3 | 17 ± 1.4 | 13 ± 1.0 | 45 ± 1.8 | 23 ± 1.8 | 3 ± 1.1 |
| Sample 4 | 16 ± 1.2 | 13 ± 0.3 | 42 ± 1.9 | 26 ± 1.8 | 4 ± 1.0 |
| Sample 5 | 17 ± 1.2 | 13 ± 1.4 | 38 ± 2.1 | 27 ± 0.7 | 5 ± 0.4 |
| Sample 6 | 19 ± 1.5 | 13 ± 1.1 | 33 ± 1.5 | 29 ± 1.2 | 6 ± 1.2 |
| Sample 7 | 20 ± 1.9 | 13 ± 1.6 | 25 ± 1.3 | 32 ± 2.2 | 10 ± 1.0 |
| Sample 8 | 23 ± 1.7 | 11 ± 1.3 | 18 ± 1.0 | 35 ± 1.5 | 13 ± 1.7 |
| Sample 9 | 22 ± 1.0 | 9 ± 1.0 | 14 ± 1.3 | 34 ± 1.1 | 21 ± 1.5 |
| Sample 10 | 22 ± 1.7 | 8 ± 0.6 | 11 ± 0.7 | 32 ± 6.1 | 26 ± 2.5 |
| Sample 11 | 22 ± 0.4 | 7 ± 1.2 | 8 ± 1.3 | 33 ± 2.2 | 30 ± 1.2 |
| Sample 12 | 20 ± 0.9 | 5 ± 0.7 | 7 ± 1.0 | 35 ± 1.3 | 32 ± 1.1 |

*The standard deviation comes from 5 different areas on each sample.

FIG. 9—Plot showing the EDS measured compositional gradients for the HEA-4 quasi-combinatorial experiment.

TABLE 6
EDS Measured Coating Compositions from the HEA-4 quasi-
combinatorial experiment

| | Al | | Cr | | Fe | | Co | | Ni | |
|---|---|---|---|---|---|---|---|---|---|---|
| | ave. | stdev. | ave. | stdev. | ave. | stdev. | ave. | stdev. | ave. | stdev. |
| Sample 1 | 16 | 1.3 | 11 | 1.4 | 2 | 0.5 | 49 | 2.0 | 22 | 1.3 |
| Sample 2 | 18 | 0.9 | 10 | 0.8 | 1 | 0.4 | 50 | 1.7 | 21 | 1.6 |
| Sample 3 | 18 | 0.6 | 10 | 0.5 | 2 | 0.4 | 47 | 1.4 | 23 | 1.4 |
| Sample 4 | 17 | 0.8 | 10 | 1.1 | 2 | 0.8 | 45 | 2.2 | 26 | 2.1 |
| Sample 5 | 18 | 1.1 | 10 | 0.8 | 4 | 0.8 | 38 | 1.7 | 30 | 1.7 |
| Sample 6 | 16 | 1.6 | 10 | 0.7 | 5 | 0.5 | 36 | 0.9 | 33 | 1.1 |
| Sample 7 | 17 | 2.5 | 10 | 0.5 | 9 | 0.9 | 27 | 2.2 | 37 | 1.1 |
| Sample 8 | 16 | 1.8 | 9 | 0.7 | 12 | 2.0 | 21 | 1.9 | 42 | 1.1 |
| Sample 9 | 16 | 1.6 | 10 | 0.8 | 18 | 1.5 | 14 | 1.1 | 42 | 1.2 |
| Sample 10 | 15 | 1.5 | 10 | 1.1 | 23 | 1.1 | 11 | 1.3 | 41 | 2.2 |
| Sample 11 | 16 | 1.5 | 10 | 1.7 | 27 | 1.9 | 8 | 1.2 | 39 | 2.4 |
| Sample 12 | 15 | 0.9 | 10 | 1.1 | 31 | 1.3 | 7 | 1.0 | 37 | 0.7 |

* The standard deviation comes from 5 different areas on each sample.

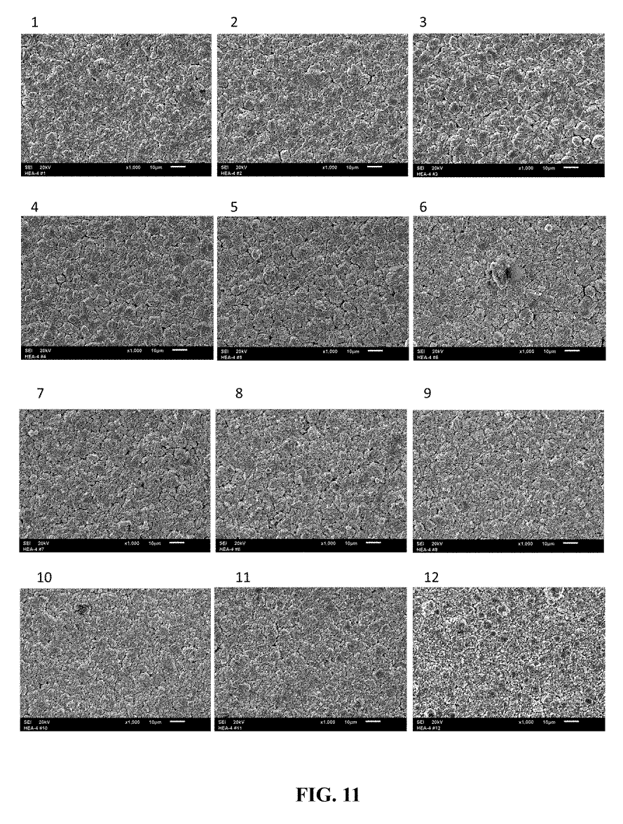

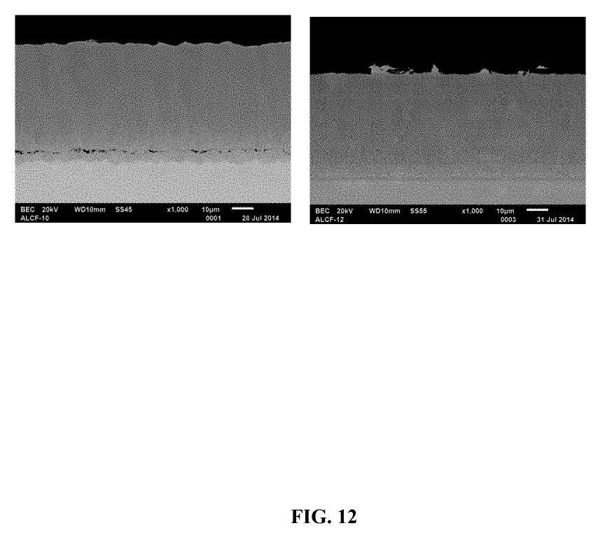

The surface microstructure of the resulting coatings is given in FIG. 10 and FIG. 11. Note that there are some microstructural variations with the change in the coating composition. The coating microstructure varied from dense appearing layers to layers with higher degree of surface roughness and the appearance of columnar porosity. The processing conditions utilized for these runs resulted in dense layers when NiCrAl alloys being deposited, FIG. 12. The HEA-1 compositions 7-12 appeared to have the most dense regions with increasing surface roughness observed in positions 1-6. HEA-4 coatings 1-12 had some surface roughness features. These results indicated the potential to increase the deposition energy (through increases in the plasma power or bias voltage) for future runs and possibly to access the cross-sectional microstructure of the as-deposited coatings in future efforts.

FIG. 10—Surface microstructure of the as-deposited bond coats from HEA-1.

FIG. 11—Surface microstructure of the as-deposited bond coats from HEA-4.

FIG. 12—NiAlCr coatings applied onto A) a grit blast substrate and B) a polished substrate. Note the improved density of the coating/substrate interface for the polished substrate.

### 7.2 Thermal Spallation Testing:

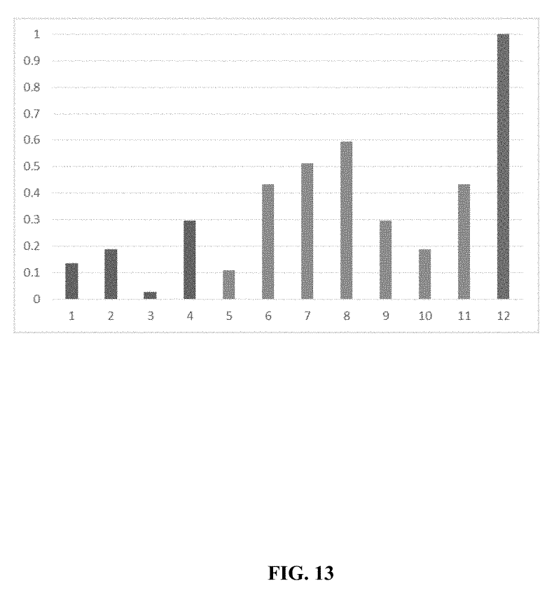

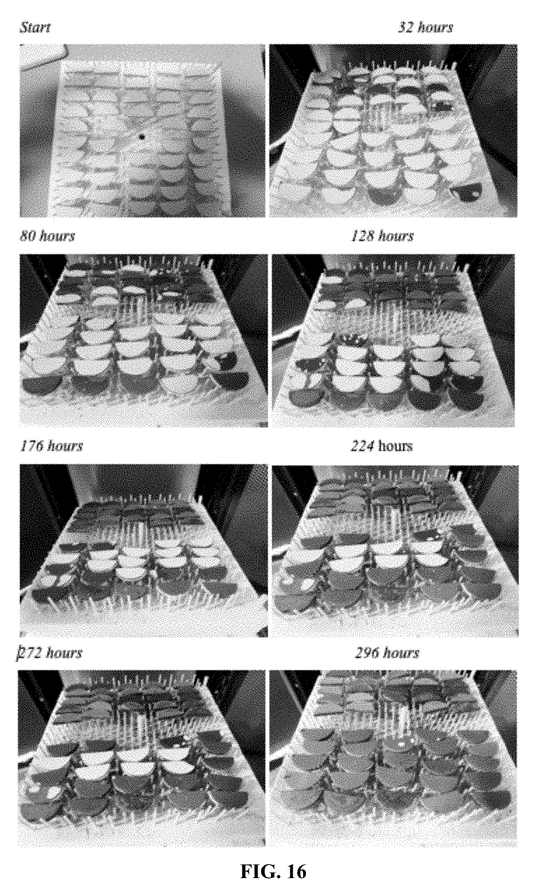

Coupons coated with complete TBC systems (HEA bond coat and TBC coating) were exposed to thermal cycling (1 hr. cycles from 1130° C. to room temperature) to screen for good performing systems. This work was performed using a thermal oxidation furnace (made by CM furnaces Inc., Bloomfield, N.J.). The relative cyclic oxidation lifetimes are given in FIGS. 13 through 15. The cyclic oxidation samples following various exposure times are given in FIG. 16. The results indicated, importantly, that the composition of the bond coats DID effect the lifetime of the TBC system so that the approach for selecting HEA compositions using this approach appears to be feasible. Two coating systems had good lifetimes (especially considering that no Hf additions were made to the bond coats in this round of testing) and fit the description of an HEA alloy. The HEA compositions identified using this approach where sample 12 from HEA-1 and samples 6-7 from HEA-4. Sample 12 from HEA-1 had a measured composition of approximately Ni—32 Cu—20 Al—7 Fe—5 Cr. Sample 7 from HEA-4 had a measured composition of approximately Ni—27 Co—17 Al—10 Cr—9 Fe.

FIG. 13—Relative thermal spallation resistance of TBC systems containing HEA bond coats from the HEA-1 quasi-combinatorial experiment. Green indicates compositions that fit the description of HEA alloys and also have promising cyclic oxidation lifetimes. Red indicates the composition does not fit the description of an HEA alloy.

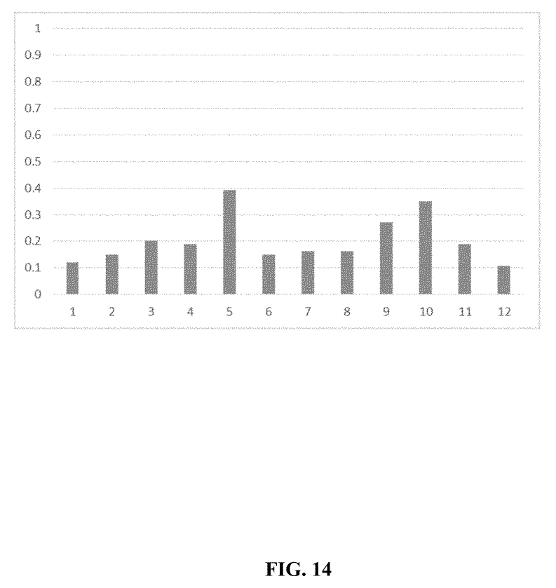

FIG. 14—Relative thermal spallation resistance of TBC systems containing HEA bond coats from the HEA-3 quasi-combinatorial experiment. Green indicates compositions that fit the description of HEA alloys and also have promising cyclic oxidation lifetimes. Red indicates the composition does not fit the description of an HEA alloy.

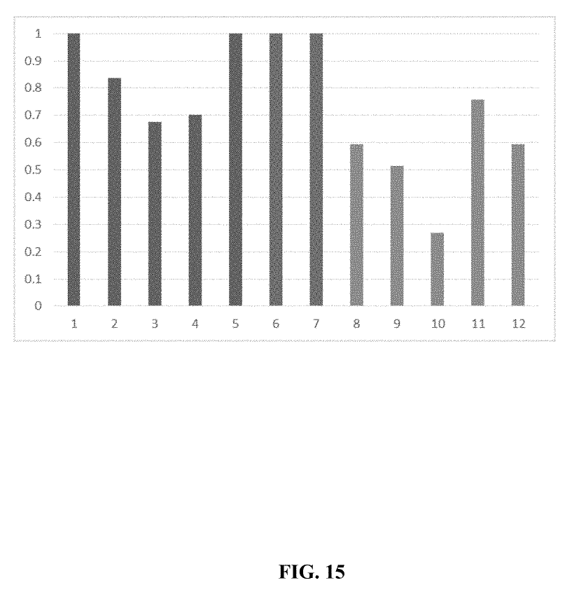

FIG. 15—Relative thermal spallation resistance of TBC systems containing HEA bond coats from the HEA-4 quasi-combinatorial experiment. Green indicates compositions that fit the description of HEA alloys and also have promising cyclic oxidation lifetimes. Red indicates the composition does not fit the description of an HEA alloy.

FIG. 16—TBC systems containing HEA bond coats during thermal spallation testing.

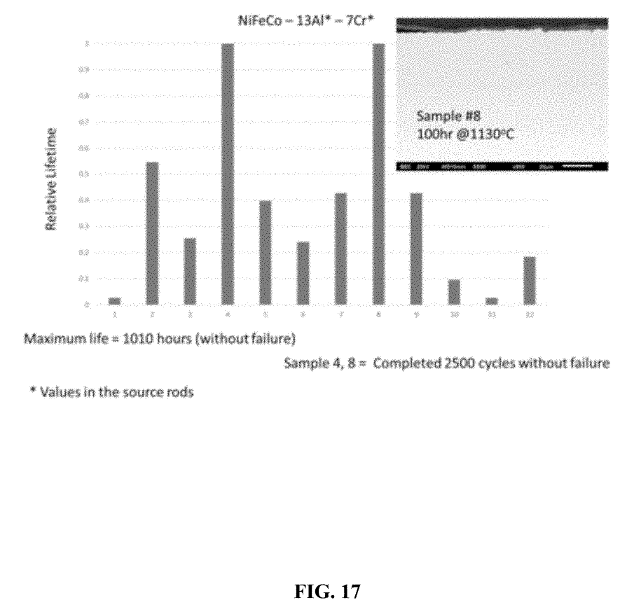

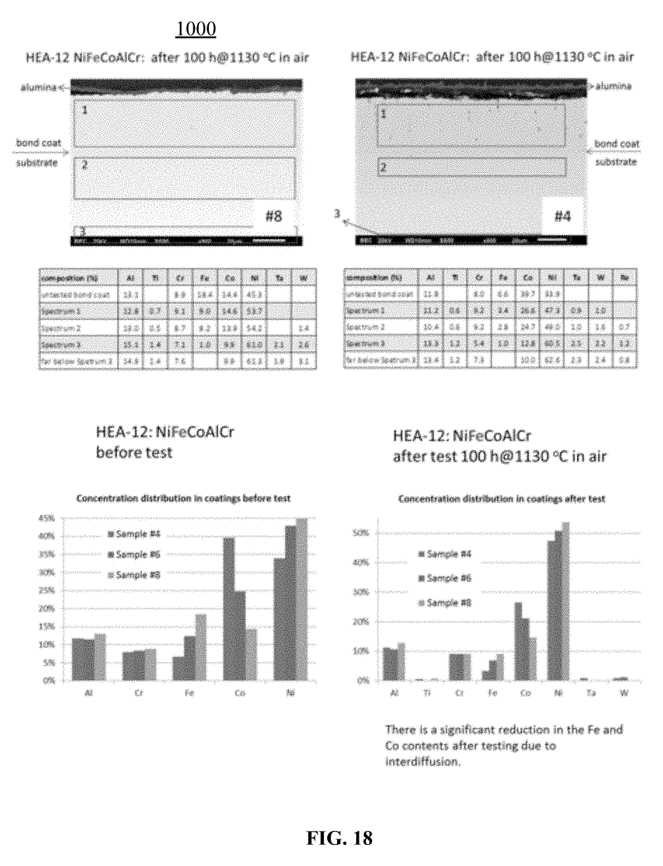

Follow-on experiments were conducted for the NiCoFeCrAl compositions and a NiCoMnCrAl system. The Cr and Al levels were reduced for the NiCoFeCrAl system to approximately 13 atomic % Al and approximately 7.5 atomic % Cr. The results indicated that the TBC system lifetime was a function of the Ni:Co:Fe ratio as previously indicated in FIG. 15 above. The results from FIG. 17 indicate that two NiCoFeAlCr compositions (#4 and #8) were superior to the others surviving more than approximately 2500-1 hour cycles from room temperature to approximately 1130° C. In FIG. 18 the composition of coatings #4 and #8 are given. Coating #4 was measured to be approximately Ni—18.4 Fe—14.4 Co—13.1 Al—8.9 Cr+<0.1 Y (at. %). Coating #8 was measured to be approximately Ni—6.6 Fe—39.6 Co—11.8 Al—8.0 Cr+<0.1 Y (atomic %).

FIG. 17—A range of NiFeCoAlCr alloy compositions were deposited and used as bond coats for TBC systems (having a 7YSZ top coat). The results indicated that the TBC system lifetimes were a function of the Ni:Fe:Co ratio with samples 4 and 8 giving the best performance.

FIG. 18—The composition of samples 4 and 8 is given both in the as-deposited condition and following thermal exposure.

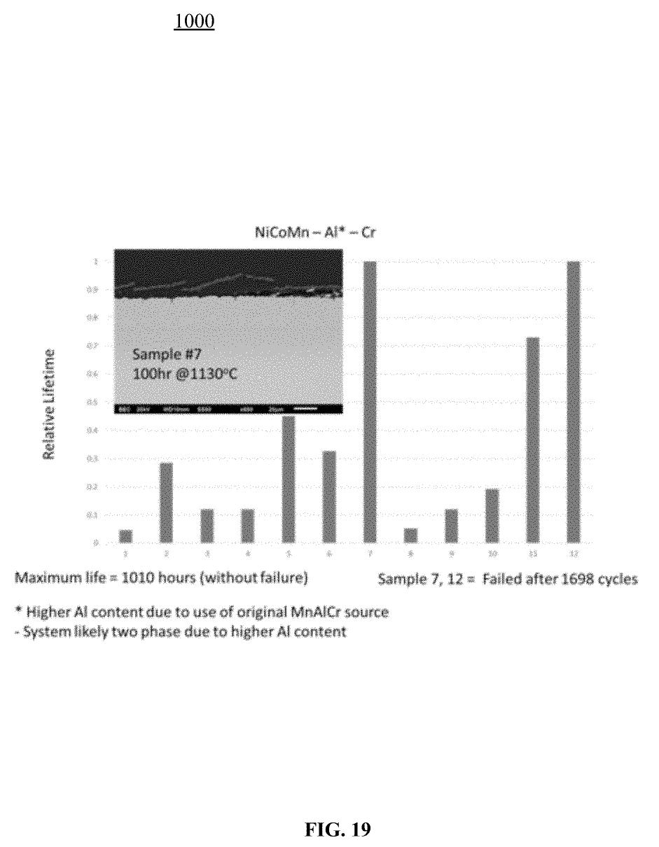

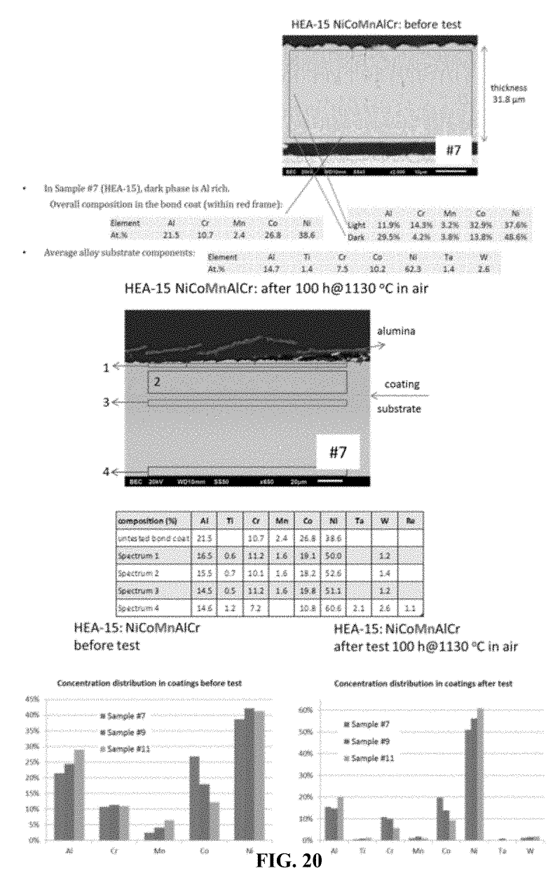

Experiments on the NiCoMnCrAl system also resulted in the identification of multiple composition shaving unexpectedly good performance. These included samples 7 and 12 that survived approximately 1698-1 hour cycles at approximately 1130° C., FIG. 19. Sample 7 had a composition of approximately Ni—26.8Co—2.5Mn—21.5Al—10.7Cr+<0.1 Y (atomic %) as shown in FIG. 20.

FIG. 19—A range of NiCoMnAlCr alloy compositions were deposited and used as bond coats for TBC systems (having a 7YSZ top coat). The results indicated that the TBC system lifetimes were a function of the Ni:Mn:Co ratio with samples 7 and 12 giving the best performance.

FIG. 20—The composition of samples 4 and 8 is given both in the as-deposited condition and following thermal exposure.

### Definitions

When the following terms are used substantively herein, the accompanying definitions apply. These terms and definitions are presented without prejudice, and, consistent with the application, the right to redefine these terms during the prosecution of this application or any application claiming priority hereto is reserved. For the purpose of interpreting a claim of any patent that claims priority hereto, each definition (or redefined term if an original definition was amended during the prosecution of that patent), functions as a clear and unambiguous disavowal of the subject matter outside of that definition.

a—at least one.

activation energy—the minimum amount of energy required to start a chemical reaction.

activity—an action, act, step, and/or process or portion thereof.

adapter—a device used to effect operative compatibility between different parts of one or more pieces of an apparatus or system.

and/or—either in conjunction with or in alternative to.

anode—a positively charged electrode via which the electrons leave a device.

aperture—an opening or hole defined by an object.

apparatus—an appliance or device for a particular purpose

associate—to join, connect together, and/or relate.

below—under in elevation.

bias—a voltage or current applied to an electrical device and/or system.

bipolar—an electrical current that may assume either of two polarities, neither of which is zero.

can—is capable of, in at least some embodiments.

carrier gas—a substance that acts to convey a coating material in a directed vapor deposition chamber, which substance is in a state such that the substance expands freely to fill any space available, irrespective of a quantity of the sub stance.

cathode—a negatively charged electrode by which electrons enter an electrical device.

cause—something that produces an effect, result, or condition.

chamber—a substantially enclosed space or cavity.

change—to make different.

choked nozzle—a spout at a terminus of a pipe, hose, or tube constructed to control a jet of a gas or liquid and severely restricts flow of the gas or liquid.

circuit board—a substrate that mechanically supports electronic components using conductive tracks, pads and other features etched and/or laminated thereon.

coat—to provide an object with a layer over a surface of the object.

coating material—a substance to be applied as a layer to a substrate.

coaxial—having a common axis.

component—a part of a larger whole.

comprising—including but not limited to.

concentration—abundance of a constituent as a percentage of a mixture.

configure—to make suitable or fit for a specific use or situation.

connect—to join or fasten together.

constructed to—designed or made for a specific use or situation.

contact—to physically touch.

convert—to transform, adapt, and/or change.

coupleable—capable of being joined, connected, and/or linked together.

coupling—linking in some fashion.

crucible—a container constructed to hold a substance, which container is constructed to allow the substance to be subjected to a gasifying temperature.

define—to establish the outline, form, or structure of.

deposit—to put a layer on a surface of an object.

determine—to obtain, calculate, decide, deduce, and/or ascertain.

device—a machine, manufacture, and/or collection thereof.

direct—to regulate a course of something.

direction—a line along which something moves.

directly—substantially with nothing in between.

directed vapor deposition process—a method via which a layer of a coating material is put on a surface of a substrate, wherein the layer is formed via condensation of an evaporated substance on the surface of the substrate, which evaporated substance is conveyed to the surface of the substrate via a carrier gas stream.

dopant—an element or compound that is inserted into a gas stream.

electrically conductive—constructed to convey electricity over a distance and having a resistivity of less than approximately 1 mΩ cm.

electrically non-conductive—constructed to substantially not conduct electricity and having a resistivity of greater than approximately 1 mΩ cm.

electrolyte—a liquid or gel that contains ions and can be decomposed by electrolysis.

electron beam—a directed stream of electrons in a gas or vacuum.

electron beam flux—an emitted stream of electrons from an electron beam source.

electron beam source—a system constructed to emit a stream of electrons in a gas or vacuum.

electronic circuit—a system comprising at least one semiconductor in one or more resistors, transistors, capacitors, inductors and/or diodes, which are electrically coupled via conductive wires or traces through which an electric current can flow.

elevation—a height above a predetermined level.

emit—to give off something.

emission direction—a primary course along which a plasma source conveys a plasma flux.

energy—power to provide heat, light, and/or work.

entirely—completely.

evaporate—to cause a change of state from a solid to a gas.

exceed—to be greater than.

expose—to make something accessible to a particular influence.

form—to cause development of something.

gas—a state of matter in which the matter is in a form of a vapor and that has neither independent shape nor volume but tends to expand indefinitely unless constrained by a barrier.

gas jet nozzle—a pipe or duct that directs a gas and accelerates the flow of the gas.

generate—to create, produce, give rise to, and/or bring into existence.

heat—to impart kinetic energy to an object and/or system such that a temperature of the object and/or system is thereby increased.

heat energy—nonmechanical energy with reference to a temperature difference between a system and its surroundings or between two parts of the same system.

higher—greater in magnitude.

hit—to impact.

hollow cathode plasma subsystem—a system comprising an electrode that defines a cavity and is constructed to impart energy to a material and thereby generate a plasma.

hot walled kettle—a vessel that acts as a melt pool in a directed vapor deposition system; the vessel comprises a roof that is substantially impervious to vapor emission; the vessel comprises an elbowed sidewall vent that causes a vapor emitted from the vessel to turn by approximately ninety degrees at least twice prior to deposition on a substrate.

impart—to transfer to.

indirect—substantially without touching.

indirectly heating—a imparting thermal energy without contacting a hot surface, such as via indirect electron beam heating.

inert carrier gas—a vapor present in a chamber that is substantially non-reactive with other substances in the chamber. For example, an inert carrier gas can comprise a noble gas (i.e., helium, argon, neon, xenon, krypton, radon, and/or oganesson) and/or gaseous nitrogen, etc.

inject—to introduce something into a directed vapor deposition chamber.

install—to connect or set in position and prepare for use.

intermingle—to mix together.

ion conducting—a material via which charged atoms or molecules can permeate.

ionic conductivity—a measure of an ability of an ionized material to move through a substance.

ionize—to convert atoms from an uncharged state to a charged state, typically via changes in an electrode count in proximity to atom nuclei.

layer—a quantity of material placed on the surface of something.

LiPON—lithium phosphorus oxynitride.

liquid free—substantially lacking any free flowing substance.

locate—to establish a position of something relative to something else.

material feeder—a subsystem that transfers a substance into a directed vapor deposition system.

may—is allowed and/or permitted to, in at least some embodiments.

melt pool—a reservoir constructed to receive a coating substance, wherein energy can be imparted to the melt pool to evaporate and/or sublimate the coating sub stance.

method—a process, procedure, and/or collection of related activities for accomplishing something.

non-line-of-site regions—portions of something that are not visible to a human via observation from a fixed point in space.

non reactive, non-melting openly porous material—a substance that will remain in a substantially solid state at temperatures utilized in a directed vapor technology process; such materials can comprise zirconia and/or tantalum, etc.

nozzle—a device that control a direction or flow characteristics of a vapor (especially to increase velocity) as the vapor enters a directed vapor deposition chamber.

operating pressure—a measure of force that a gas exerts upon a chamber in which the gas is held.

parallel—extending substantially in a same direction, approximately equidistant at all points, and substantially not converging or diverging.

particle—a small piece of solid matter.

particle-separating cyclone—a centrifugal device for separating solid particles from gases. The device typically has a substantially cylindrical portion with a substantially conical portion thereunder.

periodic—occurring at intervals.

plasma—One of four main states of matter, similar to a gas, but consisting of positively charged ions with most or all of their detached electrons moving freely about.

plasma current—an electron flow applied to a plasma source

plasma flux—a flow of plasma from a plasma source.

plasma generated ions—positively charged atoms or molecules created and conveyed by a plasma source.

plasma source unit—a system constructed to impart energy to a coating material and thereby generate a plasma.

plate—a substantially flat piece of material.

plurality—the state of being plural and/or more than one.

predetermined—established in advance.

pressure—a substantially continuous physical force exerted on or against an object by something in contact with the object.

promote—to act as a facilitator for something in a directed vapor deposition system.

provide—to furnish, supply, give, and/or make available.

pulsed—occurring in periodic bursts.

repeatedly—again and again; repetitively.

resistive heating—imparting thermal energy via an electrical current passing through a conductor.

rod—a bar of a material.

secondary—supplemental in addition to something that is primary in a directed vapor deposition system.

separate—to isolate from a mixture.

set—a related plurality.

simultaneously—occurring at substantially a same time as something else.

source—a fount from which something is emitted.

source rods—substantially cylindrical objects that provide a predetermined material (e.g., LiPON) to a deposition chamber.

source vapor—a gaseous stream that comprises a coating material to be applied as a layer to a substrate.

stream—a flow of something.

sublimated—To be transformed directly from a solid to a gas substantially without passing through a liquid phase.

substantially—to a great extent or degree.

substrate—a substance or layer upon which one or more predetermined layers are deposited.

support—to bear the weight of, especially from below.

system—a collection of mechanisms, devices, machines, articles of manufacture, processes, data, and/or instructions, the collection designed to perform one or more specific functions.

taper—a diminishment in thickness in one portion of an object relative to another portion of the object.

temperature—degree of hotness or coldness measured on a definite scale relative to a standard.

thermally conducting object—something that transfers heat with relatively low resistance.

thermally conductive material—a substance with a relatively low resistance to heat energy transfer.

thermally conducting rod—a bar of material with a relatively low resistance to heat energy transfer.

thermally evaporated—changed from a liquid state to a gaseous state via adding heat energy and/or increasing temperature.

thickness—a distance between opposite sides of an object.

thin film—a layer of material having a thickness of less than 200 microns.

transonic gas jet—a stream of vapor that has a velocity approximately the speed of sound, i.e. 965-1,236 km/h (600-768 mph).

transport—conveyance through a substance between electrodes.

vacuum—a space in which the pressure is lower than atmospheric pressure.

vapor cloud—a gaseous substance in a directed vapor deposition chamber.

vaporize—to convert via an application of energy from a solid and/or liquid state into a gas.

vapor pressure—pressure exerted by a vapor in thermodynamic equilibrium with its condensed phases (solid or liquid) at a given temperature in a closed system.

vapor source—a crucible from which gaseous stream emanates, the gaseous stream comprising a coating material to be applied as a layer to a substrate.

via—by way of and/or utilizing.

voltage—an electrical potential expressed in volt units.

wall—an upright partition with a height and length greater than its thickness and serving to enclose, divide, or define an area.

### Note

Still other substantially and specifically practical and useful embodiments will become readily apparent to those skilled in this art from reading the above-recited and/or herein-included detailed description and/or drawings of certain exemplary embodiments. It should be understood that numerous variations, modifications, and additional embodiments are possible, and accordingly, all such variations, modifications, and embodiments are to be regarded as being within the scope of this application.

Thus, regardless of the content of any portion (e.g., title, field, background, summary, description, abstract, drawing figure, etc.) of this application, unless clearly specified to the contrary, such as via explicit definition, assertion, or argument, with respect to any claim, whether of this application and/or any claim of any application claiming priority hereto, and whether originally presented or otherwise:

there is no requirement for the inclusion of any particular described or illustrated characteristic, function, activity, or element, any particular sequence of activities, or any particular interrelationship of elements;
no characteristic, function, activity, or element is “essential”;
any elements can be integrated, segregated, and/or duplicated;
any activity can be repeated, any activity can be performed by multiple entities, and/or any activity can be performed in multiple jurisdictions; and
any activity or element can be specifically excluded, the sequence of activities can vary, and/or the interrelationship of elements can vary.

Moreover, when any number or range is described herein, unless clearly stated otherwise, that number or range is approximate. When any range is described herein, unless clearly stated otherwise, that range includes all values therein and all subranges therein. For example, if a range of 1 to 10 is described, that range includes all values therebetween, such as for example, 1.1, 2.5, 3.335, 5, 6.179, 8.9999, etc., and includes all subranges therebetween, such as for example, 1 to 3.65, 2.8 to 8.14, 1.93 to 9, etc.

When any claim element is followed by a drawing element number, that drawing element number is exemplary and non-limiting on claim scope. No claim of this application is intended to invoke paragraph six of 35 USC 112 unless the precise phrase “means for” is followed by a gerund.

Any information in any material (e.g., a United States patent, United States patent application, book, article, etc.) that has been incorporated by reference herein, is only incorporated by reference to the extent that no conflict exists between such information and the other statements and drawings set forth herein. In the event of such conflict, including a conflict that would render invalid any claim herein or seeking priority hereto, then any such conflicting information in such material is specifically not incorporated by reference herein.

Accordingly, every portion (e.g., title, field, background, summary, description, abstract, drawing figure, etc.) of this application, other than the claims themselves, is to be regarded as illustrative in nature, and not as restrictive, and the scope of subject matter protected by any patent that issues based on this application is defined only by the claims of that patent.

What is claimed is:

1. A method comprising:
stabilizing adherence of a ceramic layer to a bond coat of a thermal barrier coating system, via incorporation of iron and cobalt into the bond coat at a given level.

2. A method according to embodiment 1 wherein:
said bond coat comprises MCrAlY, wherein M is selected from the group consisting of nickel, cobalt, iron and mixtures thereof.

3. A method according to embodiment 1 wherein:
chromium is present in an amount of 5-20 atomic %.

4. A method according to embodiment 1 wherein:
chromium is present in an amount of 5-10 atomic %.

5. A method according to embodiment 1 wherein:
aluminum is present in an amount of 5-20 atomic %.

6. A method according to embodiment 1 wherein:
aluminum is present in an amount of 10-15 atomic %.

7. A method according to embodiment 1 wherein:
yttrium is present in an amount of 0.01-5 atomic %.

8. A method according to embodiment 1 wherein:
yttrium is present in an amount of 0.1-1.0 atomic %.

9. A method according to embodiment 1 wherein:
iron is present in an amount of 5-20 atomic %.

10. A method according to embodiment 1 wherein:
iron is present in an amount of 8-20 atomic %.

11. A method according to embodiment 1 wherein:
cobalt is present in an amount of 10-50 atomic %.

12. A method according to embodiment 11 wherein:
cobalt is present in an amount of 25-40 atomic %.

13. A method according to embodiment 1 wherein:
cobalt is present in an amount of 10-15 atomic %.

14. A method according to embodiment 1 wherein:
nickel is present in an amount of 10-60 atomic %.

15. A gas turbine component comprising:
a TBC system having a metallic bond coat and a ceramic layer, said bond coat comprising iron and cobalt additions at a given level.

16. A gas turbine component according to claim 15, wherein:
said iron is present in an amount of 8-20 atomic %.

17. A gas turbine component according to claim 15, wherein:
said cobalt is present in an amount of 10-50 atomic %.
